(19) United States
(12) Patent Application Publication
(10) Pub. No.: US 2011/0139250 A1
(43) Pub. Date: Jun. 16, 2011

(54) BIFACIAL SOLAR CELL

(75) Inventors: Chen-Hsun Du, Taipei City (TW); Wen-Ching Sun, Taoyuan County (TW); Wei-Lun Chang, Yilan County (TW)

(73) Assignee: INDUSTRIAL TECHNOLOGY RESEARCH INSTITUTE, Hsinchu (TW)

(21) Appl. No.: 12/788,320

(22) Filed: May 27, 2010

(30) Foreign Application Priority Data
Dec. 14, 2009 (TW) 98142752

(51) Int. Cl. H01L 31/00

(52) U.S. Cl. 136/261

(57) ABSTRACT

A bifacial solar cell including a semiconductor substrate of a first conductivity type, a fixed charge layer, a first grid electrode, a semiconductor layer of a second conductivity type and a second grid electrode are provided. The fixed charge layer is located on a rear surface of the semiconductor substrate. The first grid electrode is located over the rear surface of the semiconductor substrate and electrically connected to the rear surface of the semiconductor substrate by penetrating through the fixed charge layer. The semiconductor layer is located on the front surface of the semiconductor layer. The second grid electrode is located over and electrically connected to the semiconductor layer.

### CROSS-REFERENCE TO RELATED APPLICATION

This application claims the priority benefit of Taiwan application serial no. 98142752, filed on Dec. 14, 2009. The entirety of the above-mentioned patent application is hereby incorporated by reference herein and made a part of this specification.

### BACKGROUND OF THE INVENTION

1. Field of the Invention

The present invention relates to a bifacial solar cell.

2. Description of Related Art

In recent years, the environmental problems are highly concerned. To resolve a problem of energy shortage and reduce an impact on the environment caused by using the fossil energy, research of alternative energy and renewable energy become an important topic. Since a solar cell can directly convert solar energy into electric power, and none greenhouse gases such as carbon dioxide is produced during the power generation process, the solar cell becomes a focus of attention.

A crystalline silicon solar cell is a kind of most popular solar cell. It starts from a semiconductor substrate (for example, Si). This semiconductor substrate could be N-type or P-type. Then, the one surface of semiconductor substrate is doped for opposite conductivity type to form a PN junction, where a built-in field exists thereon. The built-in field can separate carriers such as electrons and holes. When sunlight irradiates in a semiconductor substrate, the photons excite electrons in the semiconductor atoms to generate electron-hole pairs. When the excited electrons and holes are diffused to the built-in field, due to the influence of the built-in field, the holes move towards a direction of the P-type semiconductor, and the free electrons move towards a direction of the N-type semiconductor. If two electrodes are respectively connected to the P-type semiconductor and the N-type semiconductor, and are connected to an external circuit and a load, currents can flow through the load for utilization.

Most of the crystalline silicon solar cells apply a back surface field structure, by which a layer of aluminium conductive paste is screen printed on the rear surface of the P-type silicon substrate, and then a sintering process is performed. Since an Al—Si eutectic temperature is only 577° C., the aluminium of the group III elements is easy to diffuse into the silicon of the group IV elements. Therefore, after the sintering process, a P⁺ silicon layer can be generated on the rear surface of the P-type silicon substrate, and the P⁺ silicon layer and the P-type silicon substrate can form a stepped P⁺-P junction, so as to generate a back surface field (BSF) to reduce recombination of the electrons on the rear surface, so that the conversion efficiency of the solar cell would be improved.

However, since such type of the solar cell uses opaque metal as the rear surface electrode, only a single side thereof can absorb the sunlight. Therefore, such type of the solar cell is not suitable for a bifacial type building integrated photovoltaic (BIPV) serving as a curtain wall.

Since both sides of a bifacial solar cell can absorb the sunlight, it is suitable for a curtain wall application. Presently, in a HIT solar cell disclosed by a Japan Sanyo company, a plasma enhanced chemical vapor deposition (PECVD) process is used to fabricate a PN junction at a positive electrode, and a BSF structure is also fabricated on the rear surface according to the PECVD process, though a fabrication process thereof is greatly different to that of a conventional solar cell, and a fabrication equipment thereof is expensive.

### SUMMARY OF THE INVENTION

The present invention is directed to a bifacial solar cell, which could reduce the carrier recombination on the surface and increase cell efficiency.

The present invention is directed to a bifacial solar cell, which can be fabricated based on a conventional fabrication process.

The present invention is directed to a bifacial solar cell, which can be used as a bifacial type building integrated photovoltaic (BIPV).

The present invention provides a bifacial solar cell including semiconductor substrate of a first conductive type, a first fixed charge layer, a first grid electrode, a semiconductor layer of a second conductive type and a second grid electrode. The semiconductor substrate of the first conductive type includes a front surface and a corresponding rear surface, wherein the front surface represents an incident surface of a primary light, and the rear surface represents an incident surface of a secondary light. The first fixed charge layer is located on the rear surface of the semiconductor substrate of the first conductive type. The first grid electrode is located over the rear surface of the semiconductor substrate of the first conductive type and electrically connected to the rear surface of the semiconductor substrate of the first conductive type by penetrating through the first fixed charge layer. The semiconductor layer of the second conductive type is located at the front surface of the semiconductor substrate of the first conductive type. The second grid electrode is located over and electrically connected to the semiconductor layer of the second conductive type.

According to the bifacial solar cell of the present invention, a fixed charge layer is added between a rear surface of a substrate and an anti-reflection coating layer, which can prevent recombination of carriers on the rear surface and improve cell efficiency.

The bifacial solar cell of the present invention can be fabricated according to a conventional fabrication process.

According to the bifacial solar cell of the present invention, electrodes on the front surface and the rear surface are all grid-shaped, so that both sides of the cell can absorb light. Therefore, the bifacial solar cell can serve as a bifacial type building integrated photovoltaic (BIPV).

In order to make the aforementioned and other features and advantages of the present invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a cross-sectional view of a bifacial solar cell according to an embodiment of the present invention.

FIG. 2 is a cross-sectional view of another bifacial solar cell according to an embodiment of the present invention.

FIG. 3 is a flowchart illustrating a method for fabricating a bifacial solar cell of FIG. 1 according to an embodiment of the present invention.

### DESCRIPTION OF THE EMBODIMENTS

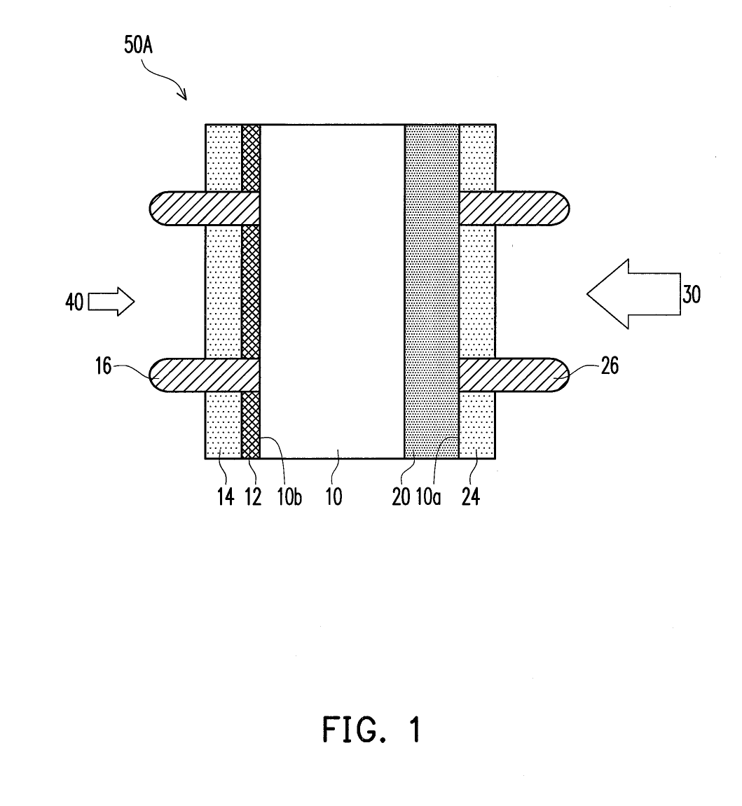

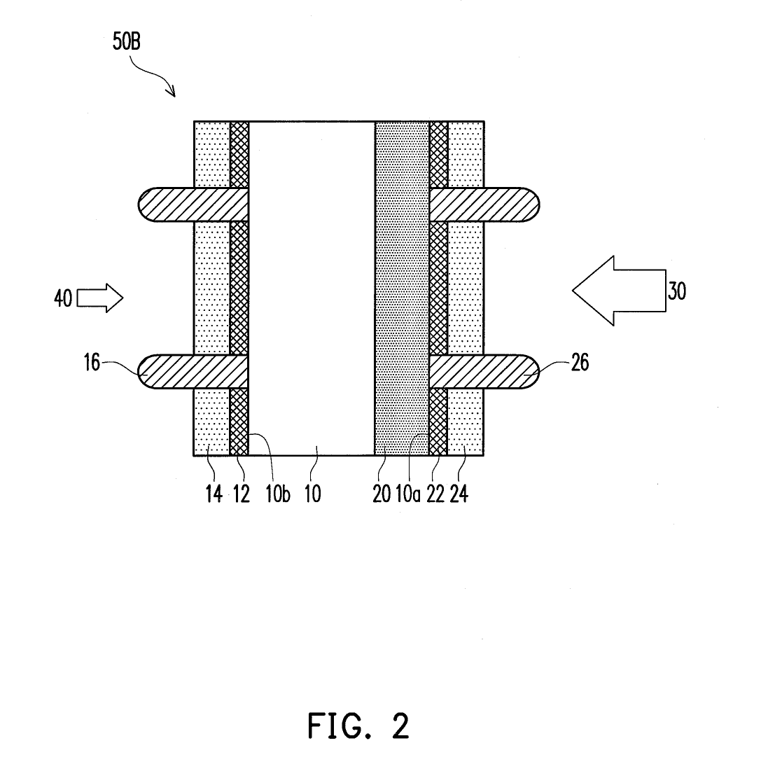

FIG. 1 is a cross-sectional view of a bifacial solar cell according to an embodiment of the present invention. FIG. 2 is a cross-sectional view of another bifacial solar cell according to an embodiment of the present invention. For simplicity's sake, the same numerals are used in the drawings and the description to refer to the same or like parts.

Referring to FIG. 1, the bifacial solar cell 50A includes a semiconductor substrate 10, a fixed charge layer 12, an anti-reflection coating layer 14, an electrode 16, a semiconductor layer 20, an anti-reflection coating layer 24 and an electrode 26.

Referring to FIG. 2, the bifacial solar cell 50B includes a semiconductor substrate 10, a fixed charge layer 12, an anti-reflection coating layer 14, an electrode 16, a semiconductor layer 20, a fixed charge layer 22, an anti-reflection coating layer 24 and an electrode 26.

The semiconductor substrate 10 is of a first conductive type, and the semiconductor layer 20 is of a second conductive type. In an embodiment, the first conductive type is a P-type, and the second conductive type is an N-type. In another embodiment, the first conductive type is the N-type, and the second conductive type is the P-type. The semiconductor substrate 10 is, for example, a crystalline silicon substrate, and has a front surface 10a and a corresponding rear surface 10b. The front surface 10a represents an incident surface of a primary light 30 under ordinary operation condition, and the rear surface represents an incident surface of a secondary light 40 under ordinary operation condition. An intensity of the primary light 30 is greater than that of the secondary light 40.

The semiconductor layer 20 is located at the front surface 10a of the semiconductor substrate 10. In an embodiment, the semiconductor layer 20 is a doped layer of the second conductive type extended inwards from the front surface 10a of the semiconductor substrate 10. A thickness of the semiconductor layer 20 is, for example, 0.1-1 μm, which can be adjusted according to an actual demand.

The fixed charge layer 12 is located on the rear surface 10b of the semiconductor substrate 10. In FIG. 1, the fixed charge layer 22 does not exist, and in FIG. 2, the fixed charge layer 22 is located on the semiconductor layer 20. A material of the fixed charge layer 12 and the fixed charge layer 22 can be Al₂O₃, SiO₂ or SiN. In an embodiment, the semiconductor substrate 10 is the P-type, the semiconductor layer 20 is the N-type, the material of the fixed charge layer 12 is Al₂O₃, and the material of the fixed charge layer 22 is SiO₂. In another embodiment, the semiconductor substrate 10 is the N-type, the semiconductor layer 20 is the P-type, the material of the fixed charge layer 12 is SiO₂, and the material of the fixed charge layer 22 is Al₂O₃. A thickness of the fixed charge layers 12 and 22 is, for example, 5-30 nm, which can be adjusted according to an actual demand.

The anti-reflection coating layer 14 is located on the fixed charge layer 12. In FIG. 1, the anti-reflection coating layer 24 is located on the semiconductor layer 20, and in FIG. 2, the anti-reflection coating layer 24 is located on the fixed charge layer 22. Materials of the anti-reflection coating layer 14 and the anti-reflection coating layer 24 can be the same or different, which can be, for example, silicon nitride.

Shapes of the electrode 16 and the electrode 26 are all grid-shaped. The electrode 16 penetrates through the anti-reflection coating layer 14 and the fixed charge layer 12, and is electrically connected to the rear surface 10b of the semiconductor substrate 10. In FIG. 1, the electrode 26 penetrates through the anti-reflection coating layer 24, and is electrically connected to the semiconductor layer 20. In FIG. 2, the electrode 26 penetrates through the anti-reflection coating layer 24 and the fixed charge layer 22, and is electrically connected to the semiconductor layer 20. Materials of the electrode 16 and the electrode 26 can be the same or different, which is, for example, metal, and the metal material comprises aluminium, silver or silver aluminium alloy, etc.

A functional principle of the bifacial solar cell of the present invention is described below.

Referring to FIG. 1, when the bifacial solar cell 50A is irradiated by light to generate electric power, electron-hole pairs generated in the semiconductor substrate 10 of the first conductive type and the semiconductor layer 20 of the second conductive type would be separated by a built-in field formed on a junction of the semiconductor substrate 10 and the semiconductor layer 20, so that the holes (or electrons) are pushed towards the semiconductor substrate 10 of the first conductive type, and are collected by the electrode 16, and the electrons (or holes) are pushed towards the second conductive type semiconductor layer 20, and are collected by the electrode 26. However, during the power generation, the electrons (or holes) probably move towards the electrode 16 due to diffusion. Then, the electrons (or holes) moved towards the electrode 16 can be repelled by charges on the fixed charge layer 12, and can be pushed towards the junction of the semiconductor substrate 10 and the semiconductor layer 20, so that the electrons (or holes) can be separated by the built-in field, and can be collected by the electrode 26. In this way, the recombination of electrons (or holes) on the rear surface are decreased, and the solar cell efficiency could be improved.

Referring to FIG. 2, when the bifacial solar cell 50B is irradiated by light to generate electric power, besides the aforementioned mechanism, during the power generation process, the holes (or electrons) probably move towards the electrode 26 due to the diffusion. Then, the holes (or electrons) moved towards the electrode 26 can be repelled by charges on the fixed charge layer 22, and can be pushed towards the junction of the semiconductor substrate 10 and the semiconductor layer 20, so that the holes (or electrons) can be separated by the built-in field, and can be collected by the electrode 16. Based on the fixed charge layers 12 and 22 disposed at both sides of the solar cell, the recombination of the carriers on the surface is decreased, and the solar cell efficiency could be improved.

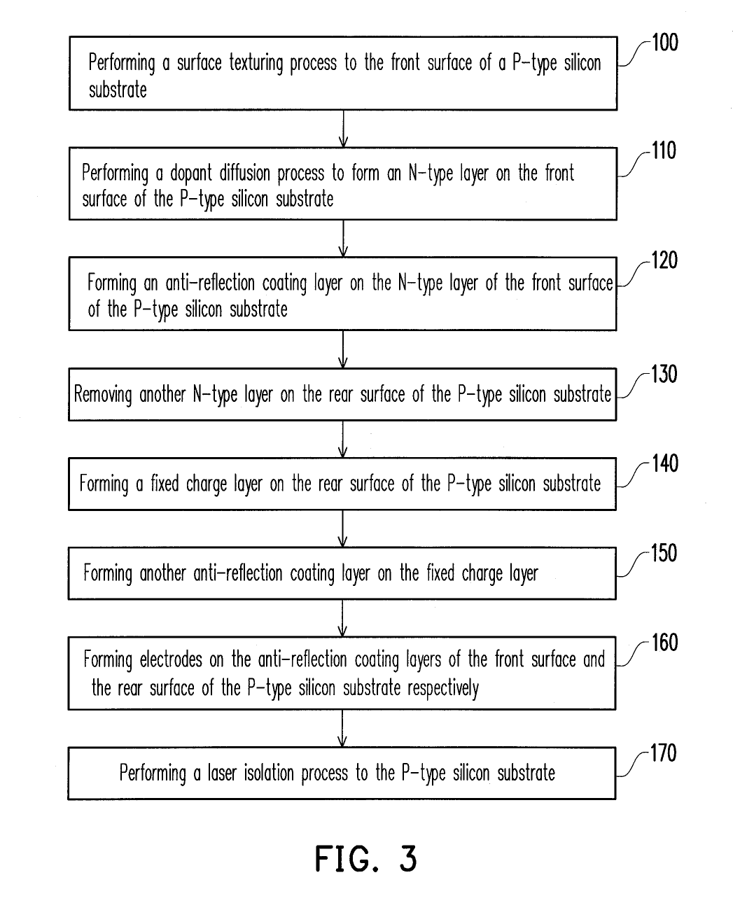

FIG. 3 is a flowchart illustrating a method for fabricating the bifacial solar cell of FIG. 1 according to an embodiment of the present invention.

Referring to FIG. 3, first, in step 100, an alkaline solution is used for surface texturing the front surface of the P-type silicon substrate. In such step, an aqueous solution containing potassium hydroxide (KOH) and isopropanol (IPA) is used to etch the silicon substrate for about 40 minutes under a temperature of 70° C.-80° C. In the present embodiment, a volume ratio of the KOH, the IPA and water is KOH(aq) (45 wt %):IPA:water=26:67:100.

Next, in step 110, a dopant diffusion process is performed to form an N-type layer on the front surface of the P-type silicon substrate. The P-type silicon substrate and the N-type layer form the PN junction. In such step, the P-type silicon substrate is, for example, sent to a diffusion furnace, and a dopant gas source is introduced, so that a phosphorus silicon glass (PSG) layer is formed on the front surface. Then, the N-type dopant diffusion is carried on under a high temperature, so as to form the N-type layer on the front surface of the P-type silicon substrate. The dopant gas source introduced into the diffusion furnace is, for example, POCl₃ or other dopant gas sources used for forming the PN junction. The above method is only one of a plurality of methods used for implementing the dopant diffusion process. Namely, such step can be implemented through the other methods known by those with ordinary skill in the art. Then, the PSG layer is removed. A method of removing the PSG layer can be a wet etching method, and an etchant used in the wet etching method is, for example, a buffered oxide etchant (BOE).

Next, in step 120, an anti-reflection coating layer is formed on the N-type layer of the front surface of the P-type silicon substrate. A material of the anti-reflection coating layer is, for example, silicon nitride, and the anti-reflection coating layer is, for example, formed through a chemical vapor deposition process. The above method is only one of a plurality of methods used for forming the anti-reflection coating layer. Namely, such step can be implemented through the other methods known by those with ordinary skill in the art.

Then, in step 130, another N-type layer formed on the rear surface of the P-type silicon substrate is removed, wherein such N-type layer is simultaneously formed when the PN junction is formed on the front surface of the P-type silicon substrate. In such step, an alkaline solution (for example, an aqueous solution containing NaOH) is used to etch the silicon substrate for about 5-10 minutes under a temperature of 75° C.-85° C. In the present embodiment, a volume ratio of the NaOH and water is NaOH:water=1:1.

Next, in step 140, a fixed charge layer is formed on the rear surface of the P-type silicon substrate. A material of the fixed charge layer comprises Al₂O₃, and a method of forming the fixed charge layer is, for example, an atomic layer deposition or a chemical vapor deposition method.

Then, in step 150, an anti-reflection coating layer is formed on the fixed charge layer on the rear surface of the P-type silicon substrate. A material of the anti-reflection coating layer is, for example, silicon nitride, and a method of forming the anti-reflection coating layer is, for example, a plasma enhanced chemical vapor deposition (PECVD) method. The above method is only one of a plurality of methods used for forming the anti-reflection coating layer. Namely, such step can be implemented through the other methods known by those with ordinary skill in the art.

Then, in step 160, electrodes are respectively formed on anti-reflection coating layers on the front surface and the rear surface of the P-type silicon substrate. In the present invention, a method of forming the electrodes comprises a screen printing process and a sintering process. In detail, metal paste containing metal powders, glass powders and organic components is screen printed on the anti-reflection coating layers, and then the sintering process is performed for curing, so as to form the electrodes. The above method is only one of a plurality of methods used for forming the electrodes. Namely, such step can be implemented through the other methods known by those with ordinary skill in the art.

Then, in step 170, a laser isolation process is performed to the P-type silicon substrate to accomplish fabrication of the solar cell. Namely, after device layers such as the anti-reflection coating layer and the electrodes are formed on the silicon substrate, the laser isolation process is performed to the layers on the silicon substrate, so as to avoid current leakage and facilitate a post packaging process. Since the isolation process is well known by those with ordinary skill in the art, a detailed description thereof is not repeated. Certainly, the above method is only one of a plurality of methods used for implementing the isolation process. Namely, such step can be implemented through the other methods known by those with ordinary skill in the art.

In the above embodiment, the P-type silicon substrate is taken as an example, though the present invention is not limited thereto. Moreover, in the above embodiment, the solar cell of FIG. 1 is taken as an example, though the solar cell of FIG. 2 can also be fabricated according to a similar method, by which only a step of forming the fixed charge layer on the N-type layer on the front surface of the P-type silicon substrate is required to be added between the steps 140 and 150, or between the steps 150 and 160.

In the bifacial solar cell of the present invention, the fixed charge layer is added between the rear surface of the semiconductor substrate and the anti-reflection coating layer, so that the charges on the fixed charge layer can repel the carriers diffused towards the rear surface electrode. Therefore, recombination of the carriers at the rear surface is avoided, and the solar cell efficiency could be improved.

The bifacial solar cell of the present invention can be fabricated based on a conventional fabrication process.

In the bifacial solar cell of the present invention, the electrodes on the front surface and the rear surface are all grid-shaped, so that both sides of the solar cell can absorb light. Therefore, the bifacial solar cell can serve as a bifacial type building integrated photovoltaic (BIPV).

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A bifacial solar cell, comprising:
a semiconductor substrate of a first conductive type, comprising a front surface and a rear surface corresponding to the front surface, wherein the front surface represents an incident surface of a primary light, and the rear surface represents an incident surface of a secondary light;
a first fixed charge layer, located on the rear surface of the semiconductor substrate of the first conductive type;
a first grid electrode, located over the rear surface of the semiconductor substrate of the first conductive type, and electrically connected to the rear surface of the semiconductor substrate of the first conductive type by penetrating through the first fixed charge layer;
a semiconductor layer of a second conductive type, located at the front surface of the semiconductor substrate of the first conductive type; and
a second grid electrode, located over and electrically connected to the semiconductor layer of the second conductive type.

2. The bifacial solar cell as claimed in claim 1, further comprising:
a first anti-reflection coating layer, located on the first fixed charge layer; and
a second anti-reflection coating layer, located on the semiconductor layer of the second conductive type.

3. The bifacial solar cell as claimed in claim 2, wherein the first fixed charge layer comprises Al₂O₃, SiO₂ or SiN.

4. The bifacial solar cell as claimed in claim 2, further comprising a second fixed charge layer located between the semiconductor layer of the second conductive type and the second anti-reflection coating layer.

5. The bifacial solar cell as claimed in claim 4, wherein the first conductive type is a P-type, the second conductive type is an N-type, and a material of the first fixed charge layer comprises Al₂O₃.

6. The bifacial solar cell as claimed in claim 5, wherein a material of the second fixed charge layer comprises SiO₂.

7. The bifacial solar cell as claimed in claim 4, wherein the first conductive type is an N-type, the second conductive type is a P-type, and a material of the first fixed charge layer comprises SiO₂.

8. The bifacial solar cell as claimed in claim 7, wherein a material of the second fixed charge layer comprises Al₂O₃.
